(19) United States
(12) Patent Application Publication
(10) Pub. No.: US 2025/0313717 A1
(43) Pub. Date: Oct. 9, 2025

(54) ALKANOLAMINES AS SI REMOVAL RATE ENHANCERS FOR SI POLISH

(71) Applicant: FUJIMI INCORPORATED, Aichi (JP)

(72) Inventors: Sean Fontenot, Tualatin, OR (US); Shawn Decker, Tualatin, OR (US)

(21) Appl. No.: 19/084,160

(22) Filed: Mar. 19, 2025

Related U.S. Application Data
(60) Provisional application No. 63/631,570, filed on Apr. 9, 2024.

(51) Int. Cl. C09G 1/02; H01L 21/306

(52) U.S. Cl. CPC C09G 1/02; H01L 21/30625

(57) ABSTRACT

The present disclosure relates to chemical mechanical polishing (CMP) compositions for polishing silicon (Si) surfaces. In particular, the CMP composition includes a first and second removal rate enhancer and a silica abrasive to provide a composition with advantageous properties such as high Si removal rate while also maintaining low polish debris formation.

### CROSS-REFERENCE TO RELATED APPLICATIONS

The present application is based on U.S. Provisional Patent Application No. 63/631,570, filed on Apr. 9, 2024, the disclosure of which is incorporated herein by reference in its entirety.

### TECHNICAL FIELD

The present disclosure relates to chemical mechanical polishing (CMP) compositions comprising a first and second removal rate enhancer and a silica abrasive. More particularly, the first removal rate enhancer is an alkanolamine, and the second removal rate enhancer is a basic amino acid. This combination provides advantageous properties such as high silicon removal rate while also maintaining low polish debris formation, thus providing compositions well suited for polishing a silicon surface.

### BACKGROUND

Silicon, as the first-generation semiconductor material, has been dominating a major market share of the semiconductor industry. Compared with SiC, GaN and other semiconductor materials, silicon offers superior performance in the integrated circuit (IC) industry owing to its low cost, copious storage and mature design and manufacture. The manufacture of ICs uses the commonly utilized global planarization technique known as chemical mechanical polishing (CMP).

CMP is a process in which material is removed from a surface of a substrate (such as a semiconductor wafer) and the surface is polished (planarized) by coupling a physical process, such as abrasion, with a chemical process, such as oxidation or chelation. In its most rudimentary form, CMP involves applying a slurry to the surface of the substrate or a polishing pad that polishes the substrate. This process achieves both the removal of unwanted material and planarization of the surface of the substrate. It is not desirable for the removal or polishing process to be purely physical or purely chemical, but rather comprise a synergistic combination of both.

The CMP polishing pad is a most important consumable as it has a dominating effect on the polishing process output. The structure and material properties of the polishing pad can determine the material removal rate and planarization ability. In addition, the polishing pad is responsible for distributing the slurry containing abrasive particles to the wafer surface for the removal of material. When insoluble polish debris to be described later is formed during the polishing process, the insoluble polish debris causes clogging of the polishing pad thereby likely forming scratches on the polished surface. The formation of scratches on the wafer surface, in turn, can lead to severe circuit failure, low yield of devices and potential reliability issues.

In recent years, the design of wafers has continued to advance towards a steady reduction in the wafer size and a gradual increase in the wafer's diameter, which also pose great challenges in the CMP technology of the silicon wafers. For example, a reduction in size makes it even more critical to control the formation of scratched during CMP.

Thus, there is a great need to develop polishing compositions, which can enhance the removal rate of silicon from wafers while at the same time minimizing debris formation. These and other challenges may be addressed by the subject matter disclosed herein.

### SUMMARY

In accordance with the purpose(s) of the currently disclosed subject matter or problems to be solved by the invention, as embodied and broadly described herein, it is an object of the present invention to provide a composition that facilitates improvement in removal of silicon, and the like, from a substrate. It is another object of the present invention to provide a composition and a method for maintaining low debris formation formed as polishing by-products during CMP.

Accordingly, the presently disclosed subject matter in one aspect relates to a polishing composition comprising a silica abrasive, a first removal rate enhancer and a second removal rate enhancer, wherein the first removal rate enhancer is an alkanolamine and the second removal rate enhancer is a basic amino acid, and a pH of the polishing composition is in a basic region. Incidentally, the silica abrasive means a silica-containing abrasive, which consists preferably of silica (specifically colloidal silica).

In another aspect, the subject matter described herein is directed to a method for polishing a substrate, the method comprising the steps of: 1) providing the polishing composition as disclosed herein; 2) providing a substrate, wherein the substrate comprises a silicon-containing layer; and 3) polishing the substrate with the polishing composition to provide a polished substrate.

### DETAILED DESCRIPTION

The present invention can be understood more readily by reference to the following detailed description of the invention and the examples included therein.

Before the present compounds, compositions, articles, systems, devices, and/or methods are disclosed and described, it is to be understood that they are not limited to specific synthetic methods unless otherwise specified, or to particular components unless otherwise specified, as such may, of course, vary. It is also to be understood that the terminology used herein is for describing particular aspects only and is not intended to be limiting. Although, any methods and materials that are similar or equivalent to those described herein can be used in the practice or testing of the present invention, example methods and materials are now described.

Described herein are polishing compositions comprising a silica abrasive, a first removal rate enhancer and a second removal rate enhancer. These polishing compositions are intended for polishing a substrate where the polishing compositions exhibit at least one benefit such as: 1) a high silicon removal rate (RR); 2) a low insoluble polish debris formation during CMP; and 3) a minimal change in turbidity of the polishing composition observed as the pH of the polishing composition decreases as a result of 2). The polishing compositions more preferably achieve a low removal rate of tungsten (W), silicon nitride (SiN), titanium nitride (TiN), silicon oxide made from tetraethoxysilane (TEOS), copper (Cu) and/or molybdenum (Mo).

The high silicon removal rate, low insoluble polish debris formation during CMP, and a minimal change in turbidity of the polishing composition observed as the pH of the polishing composition decreases are key properties. Compositions exhibiting these key properties may be obtained by use of specific components. For example, in an embodiment, a polishing composition comprising a silica abrasive, a first removal rate enhancer and a second removal rate enhancer maintains low insoluble polish debris formation.

The polishing composition described herein may be used to polish silicon-containing substrates.

Incidentally, the “polishing composition” herein may merely be called “composition”. “X to Y” is used as a meaning including the numerical values written before and after thereof (X and Y) as the lower limit value and upper limit value, and means “X or more and Y or less.” When more than one “X to Y” are written, for example, when “X1 to Y1, or X2 to Y2” are written, each numerical value is disclosed as the upper limit, each numerical value is disclosed as the lower limit, and all combinations of these upper limits and lower limits are disclosed (i.e., these disclosures can be lawful basis for amendments.) Specifically, the amendment of being X1 or more, amendment of being Y2 or less, amendment of being X1 or less, amendment of being Y2 or more, amendment of being X1 to X2, amendment of being X1 to Y2, and the like need to be all considered as lawful. Incidentally, the description “X or more” means X or more than X, thereby including the meaning of “more than X.” Similarly, the description “Y or less” means Y or less than Y, thereby including the meaning of “less than Y.” Additionally, unless otherwise specified, operations and measurement of physical properties, and the like are measured under the conditions of room temperature (20 to 25° C.)/relative humidity 40 to 50% RH. Incidentally, the concentration described herein may be a POU (point of use) concentration or a concentration before diluting to the POU concentration. Dilution factor may be 2 to 10×. Additionally, it is to be understood that the combinations of all embodiments and descriptions disclosed herein are disclosed in the present application. In other words, it is to be understood that the disclosures can be a basis for amendments. Additionally, when descriptions on a content and concentration of each component are found, the content and concentration in the case of containing 2 or more kinds of components may be a total amount thereof.

### A. Definitions

Listed below are definitions of various terms used to describe this invention. These definitions apply to the terms as they are used throughout this specification, unless otherwise limited in specific instances, either individually or as part of a larger group.

As used in the specification and the appended claims, the singular forms “a.” “an” and “the” include plural referents unless the context clearly dictates otherwise. Thus, for example, reference to “an abrasive” or “a pH-adjusting agent” includes mixtures of two or more such abrasives or pH-adjusting agents.

Ranges can be expressed herein as from “about” one particular value, and/or to “about” another particular value. When such a range is expressed, another aspect includes from the one particular value and/or to the other particular value. Similarly, when values are expressed as approximations, by use of the antecedent “about.” it will be understood that the particular value forms another aspect. It will be further understood that the endpoints of each of the ranges are significant both in relation to the other endpoint, and independently of the other endpoint. It will also be understood that there are a number of values disclosed herein, and that each value is herein disclosed as “about” that particular value in addition to the value itself. For example, if the value “10” is disclosed, then “about 10” is also disclosed. It will also be understood that each unit between two particular units is also disclosed. For example, if 10 and 15 are disclosed, then 11, 12, 13, and 14 are also disclosed. About X (X is a numerical value) herein may mean to further include ±10% or ±5% of X, and ±10%, if given as an example, means X×0.9 to X×1.1. In addition, about X may be X itself.

References in the specification and concluding claims to parts by weight of a particular element or component in a composition denote the weight relationship between the element or component and any other elements or components in the composition or article for which a part by weight is expressed. Thus, in a compound containing 2 parts by weight of component “X” and 5 parts by weight of component “Y.” “X and Y” are present at a weight ratio of 2:5 and are present in such ratio regardless of whether additional components are contained in the compositions.

A weight percent (wt. %) of a component, unless specifically stated to the contrary, is based on the total weight of the vehicle or composition in which the component is included.

As used herein, the terms “optional” and “optionally” mean that the subsequently described event or circumstance can or cannot occur, and that the description includes instances where said event or circumstance occurs and instances where it does not.

### B. Polishing Composition

The fundamental mechanism of CMP is to soften a surface layer by chemical reaction and then remove the softened layer by mechanical force with abrasive particles. However, the role of CMP is not only material removal, but also planarization, surface smoothening, uniformity control, defect reduction and more. Semiconductor yield enhancement is thus influenced by CMP processing.

The polishing compositions disclosed herein provide high silicon removal rates. In addition, the disclosed polishing compositions maintain low insoluble polish debris formation while exhibiting high silicon removal rates. pH of the polishing compositions disclosed herein may be adjusted to a basic region (e.g., pH of about 9.0 to about 11.0.)

For adjusting pH of the polishing compositions to a basic region, an alkaline component may be contained in the polishing compositions. Not to be bound by any theory, but although pH of the polishing composition is adjusted to a basic region (e.g., pH of about 9.0 to about 11.0) on the whole, a part of the polishing composition may have an acidic microscopic region momentarily. A site of such a microscopic region can vary constantly by molecular motion of components contained in the polishing composition, but in the acidic region the silica abrasive and/or the silicon-containing layer being polished can be dissolved in the form of monosilicic acid. The resultant by the reaction of the monosilicic acid and the above alkaline component is typically water insoluble and hence becomes insoluble polish debris as aggregates. This aggregates cause clogging of the polishing pad and may deteriorate quality of the polished surface in the end. The aggregates, once formed, can only be dissolved with a strong alkaline substance due to which the polishing composition is rather designed so that the aggregates are not formed.

The disclosed alkanolamines as the alkaline component do not promote and/or accelerate the formation of aggregates, which was surprising and unexpected. Presumably, the reactant of the specific alkanolamines disclosed herein and monosilicic acid is water soluble due to which it is considered that such things do not happen. Thus, the disclosed alkanolamines provide high silicon removal rates while at the same time significantly reducing the amount of polish debris formation in the disclosed polishing composition. For verifying that the formation of aggregates is not promoted and/or accelerated, such phenomena were pseudo-reproduced in an example to be described later. More specifically, the turbidity of the composition whose pH is acidic and the turbidity of the composition whose pH is the original (pH is basic) are contrasted.

The amount of the insoluble polish debris present in the polishing composition can be determined as a function of turbidity, i.e., the higher the amount of insoluble polish debris the more turbidity in the polishing composition is detected. It has been observed that turbidity typically increases as the pH of polishing compositions change, specifically as the pH of the polishing compositions decrease. A drop in pH of the polishing compositions has been shown to promoted/accelerated the formation of aggregates particularly in the presence of the removal rate enhancer containing a primary amine group. This formation of aggregates results in an increase in turbidity. Thus, changes in turbidity as the pH of the polishing compositions decrease is associated with the formation of insoluble polish debris. Polishing compositions exhibiting minimal changes in turbidity over a certain pH range with minimal formation of insoluble polish debris would therefore be highly desirable.

The polishing compositions disclosed herein are buffered to maintain a high pH while achieving high polishing rates without producing polish debris during CMP. Furthermore, the polishing compositions disclosed herein exhibit minimal changes in turbidity over a wide pH range when evaluated in the “Fujimi Turbidity Protocol”, which is described in more detail below.

### 1. Abrasive

The polishing composition described herein contains an abrasive. The abrasive is typically a metal oxide abrasive preferably selected from the group consisting of silica, alumina, titania, zirconia, germania, ceria and mixtures thereof. In some embodiments, the abrasive is silica. In some embodiments, the abrasive is not surface modified.

In some embodiments, the abrasive is either a commercial product or a synthetic product. As a method for producing colloidal silica, for example, a sodium silicate method and a sol-gel method can be exemplified, and colloidal silica produced by either method can be used preferably as the abrasive of the present invention. However, in the light of reducing metal impurities, colloidal silica produced by the sol-gel method, which can produce colloidal silica at high purity, is more preferable.

The abrasive can have any suitable particle size. For example, the grains of the abrasive can have an average secondary particle size of from about 5 nm to about 150 nm, from about 5 nm to about 120 nm, from about 5 nm to about 100 nm, from about 10 nm to about 90 nm, from about 20 nm to about 80 nm, from about 25 nm to about 70 nm, from about 25 nm to about 60 nm, from about 25 nm to about 50 nm, from about 25 nm to about 40 nm, or from about 30 nm to about 40 nm. For example, the grains of the abrasive can have an average secondary particle size of from about 50 nm to about 90 nm, from about 60 nm to about 80 nm, or from about 65 nm to about 75 nm. In some embodiments, the grains of the abrasive can have an average secondary particle size of 70 nm. The average secondary particle size can be measured by use of an any suitable method known in the art (e.g., by light scattering such as using Zetasizer Nano ZS made by Malvern Panalytical Ltd.)

The abrasive can have any suitable surface area. For example, the abrasive can have an average BET surface area of about 50 m²/g or more, about 60 m²/g or more, about 70 m²/g or more, about 80 m²/g or more. Alternatively, or in addition, the abrasive can have an average surface area of about 130 m²/g or less, about 120 m²/g or less, about 110 m²/g or less, about 100 m²/g or less, about 90 m²/g or less. In some embodiments, the abrasive can have an average surface area in a range from about 10 m²/g to about 150 m²/g, from about 20 m²/g to about 140 m²/g, from about 30 m²/g about 130 m²/g, from about 40 m²/g to about 120 m²/g, from about 50 m²/g to about 110 m²/g, from about 60 m²/g to about 100 m²/g, from about 65 m²/g to about 95 m²/g, from about 70 m²/g to about 90 m²/g, or from about 75 m²/g to about 85 m²/g.

The silanol group density on the silica surface of the abrasive can vary. In some embodiments, the average silanol group density on the silica surface of the abrasive grains contained in the polishing composition of the present invention is 10.0 nm⁻² or less. If the average silanol group density is more than 10.0 nm⁻², hardness of the abrasive grains is low, and the polishing speed is accordingly lowered.

The average silanol group density on the surface of the abrasive grains is preferably 9.0 nm⁻² or less and is more preferably 8.0 nm⁻² or less and is much more preferably 7.0 nm⁻² or less. The average silanol group density on the surface of the abrasive grains is 1.0 nm⁻² or more, 2.0 nm⁻² or more, 3.0 nm⁻² or more, 4.0 nm⁻² or more, and is 5.0 nm⁻² or more.

In some embodiments, the average silanol group density on the surface of the abrasive grains is from about 1.0 nm⁻² to about 10.0 nm⁻², from about 2.0 nm⁻² to about 9.0 nm⁻², from about 3.0 nm⁻² to about 8.0 nm⁻², from about 4.0 nm⁻² to about 7.5 nm⁻², from about 5.0 nm⁻² to about 7.0 nm⁻².

A lower limit of the average silanol group density is generally 0.

The number of silanol groups per unit surface area of the abrasive grains can be calculated by the Sears method using neutralization titration described in “Determination of Specific Surface Area of Colloidal Silica by Titration with Sodium Hydroxide.” Analytical Chemistry, 1956, 28 (12). pp. 1982-1983, by G. W. Sears. The calculation formula for the number of silanol groups is calculated by the following equation.

$$ρ = ( c \times a \times {N}_{A} ) / ( C \times S )$$

ρ: Number of silanol groups [count/nm^{2]}
c: Concentration of sodium hydrate solution used in titration [mol/L]
a: Amount of sodium hydrate solution having pH of 4 to 9 added dropwise [ml]
N_{A}: Avogadro's number (6.022×10²³ [count/mol])
C: Mass of silica [g]
S: BET specific surface area [nm²/g]

The number of silanol groups per unit surface area of the abrasive grains can be controlled by selection of the method for producing abrasive grains, or the like.

Moreover, the abrasive grains may be surface-modified as long as their average silanol group density is within the above-described range. In particular, colloidal silica with organic acid immobilized thereto is preferable. Such immobilization of the organic acid to surfaces of the colloidal silica contained in the polishing composition is made by, for example, chemically bonding functional groups of the organic acid with the surfaces of the colloidal silica. The organic acid is not immobilized to the colloidal silica just by allowing the colloidal silica and the organic acid to coexist. If immobilizing sulfonic acid that is a kind of such organic acid to the colloidal silica, for example, a method described in “Sulfonic acid-functionalized silica through quantitative oxidation of thiol groups”. Chem. Commun. 246-247 (2003) can be adopted. More specifically, by coupling a silane coupling agent having thiol groups such as 3-mercaptopropyltrimethoxysilane with the colloidal silica, and subsequently oxidizing the thiol groups with hydrogen peroxide, the colloidal silica with the sulfonic acid immobilized to its surface can be obtained. Alternatively, if immobilizing carboxylic acid to the colloidal silica, for example, a method described in “Novel Silane Coupling Agents Containing a Photolabile 2-Nitrobenzyl Ester for Introduction of a Carboxy Group on the Surface of Silica Gel”. Chemistry Letters, 3, 228-229 (2000)″ can be adopted. More specifically, by coupling a silane coupling agent containing photolabile 2-nitrobenzyl ester with the colloidal silica and subsequently irradiating the colloidal silica with light, the colloidal silica with carboxylic acid immobilized to its surface can be obtained.

Incidentally, the abrasive grains used in the present Working examples and Comparative Examples are not surface-modified.

The amount of abrasive present in the disclosed polishing compositions can vary. In some embodiments, the amount of abrasive in the polishing composition is about 0.01 wt. % or more, about 0.05 wt. % or more, about 0.1 wt. % or more, about 0.15 wt. % or more, about 0.2 wt. % or more, about 0.25 wt. % or more, about 0.3 wt. % or more, about 0.35 wt. % or more, or about 0.4 wt. % or more. Alternatively, or in addition, the amount of abrasive in the polishing composition can be about 1 wt. % or less, about 0.75 wt. % or less, about 0.5 wt. % or less, about 0.45 wt. % or less, about 0.40 wt. % or less, about 0.35 wt. % or less, about 0.30 wt. % or less, about 0.25 wt. % or less, about 0.2 wt. % or less, about 0.15 wt. % or less, or about 0.1 wt. % or less. In some embodiments, the amount of abrasive in the polishing composition can be in a range from about 0.01 wt. % to about 1 wt. %, about 0.05 wt. % to about 0.75 wt. %, from about 0.1 wt. % to about 0.5 wt. %, from about 0.15 wt. % to about 0.45 wt. %, from about 0.2 wt. % to about 0.4 wt. % from about 0.25 wt. % to about 0.35 wt. %. In some embodiments, the amount of abrasive in the polishing composition can be about 10 wt. % or less, or 5 wt. % or less

While the abrasive can be of any reasonable size, the size of the abrasive influences the smoothness of the finish obtained. Precision polishing operations materials such as optical components, plastics, metals, gemstones, semiconductor components, and the like typically involve the use of abrasives with smaller sizes. For example, compositions for use in connection with precision polishing involve suspensions of abrasives with smaller average particle sizes.

In some embodiments, the abrasive comprises silica. In some embodiments, the abrasive substantially comprises silica. In some embodiments the abrasive comprises colloidal silica. In some embodiments, the abrasive substantially comprises colloidal silica. As used herein. “substantially” means that 95% by weight or more, preferably 98% by weight or more, more preferably 99% by weight or more of the particles constituting the abrasive are silica (particularly, colloidal silica), and it includes that 100% by weight of the particles are silica (particularly, colloidal silica).

The abrasive is suspended in the compositions disclosed herein and is colloidally stable. The term colloid refers to the suspension of abrasive particles in the liquid carrier. Colloidal stability refers to the maintenance of the suspension over time.

In the context of this invention, an abrasive suspension is considered colloidally stable if, when the composition is stored in a 500 mL cylinder bottle and allowed to stand without agitation for a time period of two hours at room temperature (“RT” means about 25° C.). After that time, the average secondary particle size is measured at room temperature. The composition then continues to be stored at 55° C. for another 36 days, before it is allowed to reach room temperature. Another average secondary particle size measurement is taken at room temperature and the stability index is calculated based on the equation below:

Index=[average secondary particle size(after stored at 55° C. for 36 days)−average secondary particle size (at RT;0 day)]/average secondary particle size (at RT;0 day)

The criteria is such that for the Index to be desirable it has to be less than or equal to 0.3, and preferably is less than or equal to 0.1.

### 2. First Removal Rate Enhancer

In one aspect, the polishing composition may comprise a first removal rate enhancer to enhance the Si removal rate when polishing silicon-containing surfaces. In some embodiments, the first removal rate enhancer is an alkanolamine. In some embodiments, the alkanolamine is without a primary amine group. In some embodiments, the alkanolamine comprises 1 or 2 nitrogen atoms. In some embodiments, the alkanolamine contains no more than 1 nitrogen atom. In some embodiments, the alkanolamine contains 2 nitrogen atoms. In some embodiments, the alkanolamine contains no more than 1 nitrogen atom. Not to be bound by any theory, but it is believed that the disclosed alkanolamines are alkaline components that less likely form insoluble polish debris.

In some embodiments the alkanolamine contains at least one oxygen atom. In some embodiments, the alkanolamine contains 1 or 2 oxygen atoms. In some embodiments, alkanolamine contains 1 oxygen atom. In some embodiments, the alkanolamine contains 2 oxygen atoms. In some embodiments, the alkanolamine contains one nitrogen atom and one oxygen atom. In some embodiments, the alkanolamine contains one nitrogen atom and two oxygen atoms. In some embodiments, the alkanolamine contains two nitrogen atoms and one oxygen atom.

In some embodiments, the alkanolamine is represented by N (R¹) (R²) (R³), R¹ to R³ are each independently selected from a hydrogen atom, an alkyl group having 1 to 4 carbon atoms, and a hydroxy group-substituted alkyl group having 1 to 4 carbon atoms, provided that at least one of R¹ to R³ is a hydroxy group-substituted alkyl group having 1 to 4 carbon atoms. In some embodiments, R¹ to R³ are each independently an alkyl group having 1 to 4 carbon atoms, an alkyl group having 1 to 3 carbon atoms, or an alkyl group having 1 or 2 carbon atoms. In some embodiments, R¹ to R³ are each independently hydroxy group-substituted alkyl groups having 1 to 4 carbon atoms, hydroxy group-substituted alkyl groups having 1 to 3 carbon atoms, or hydroxy group-substituted alkyl groups having 1 or 2 carbon atoms. In some embodiments, the number of hydroxy groups in the hydroxy group-substituted alkyl group having 1 to 4 carbon atoms can be 1 to 3, 1 or 2. In some embodiments, the number of hydroxy groups in the hydroxy group-substituted alkyl group having 1 to 3 carbon atoms can be 1 to 3, 1 or 2. In some embodiments, the number of hydroxy groups in the hydroxy group-substituted alkyl group having 1 or 2 carbon atoms can be 1 to 3, 1 or 2.

In some embodiments, in N (R¹) (R²) (R³), R¹ is an alkyl group having 1 to 4 carbon atoms wherein one hydroxy group is substituted, R² is a hydrogen atom, and R³ is an alkyl group having 1 to 4 carbon atoms.

In some embodiments, in N (R¹) (R²) (R³), R¹ is an alkyl group having 1 to 4 carbon atoms wherein one hydroxy group is substituted, R² is a hydroxy group-substituted alkyl group having 1 to 4 carbon atoms, and R³ is an alkyl group having 1 to 4 carbon atoms.

In some embodiments, in N (R¹) (R²) (R³), R¹ is an alkyl group having 1 to 4 carbon atoms wherein one hydroxy group is substituted, R² is an alkyl group having 1 to 4 carbon atoms, and R³ is an alkyl group having 1 to 4 carbon atoms.

In some embodiments, the alkanolamine is acyclic. In such embodiments, the nitrogen atom is a primary, secondary or tertiary amine. In such embodiments, the oxygen atom is included in a hydroxy group (—OH). In some embodiments, alkanolamine contains at least one secondary amine and one hydroxy group. In some embodiments, the alkanolamine contains a tertiary amine and at least one hydroxy group. In some embodiments, the alkanolamine contains no more than 1 nitrogen atom.

In some embodiments, the alkanolamine is cyclic. In some embodiments, the alkanolamine contains an alkyl heterocycle, wherein the alkyl heterocycle contains at least 1 nitrogen and/or oxygen atom.

In some embodiments, the alkanolamine contains less than about 12 atoms except hydrogen atoms, less than about 11 atoms, less than about 10 atoms, less than about 9 atoms, less than about 8 atoms, less than about 7 atoms, less than about 6 atoms, or less than about 5 atoms.

In some embodiments, alkanolamine is selected from the group consisting of monomethyl ethanolamine (MMEA), methyl diethanol amine (MDEA), dimethyl ethanolamine (DMEA) and a combination thereof. In some embodiments, the alkanolamine is MMEA or MDEA. In some embodiments, the alkanolamine is MMEA.

In some embodiments, the amount of first removal rate enhancer (i.e., alkanolamine) has an effect on the properties of the polishing composition, such as Si RR and/or turbidity of the polishing composition. As discussed herein, the first removal rate enhancer minimizes debris formation during polishing of Si-surfaces. The amount of the first removal rate enhancer may range from about 0.01% to about 1%, from about 0.01% to about 0.5%, from about 0.05% to about 0.5%, from about 0.05% to about 0.25%, from about 0.10% to about 0.25%, from about 0.10% to about 0.20%, or from about 0.12% to about 0.18%. In some embodiments, the first removal rate enhancer may range from about 0.1% to about 0.3%, from about 0.1% to about 0.25%, from about 0.1% to about 0.2% or from about 0.1% to about 0.15%. In some embodiments, the first removal rate enhancer is present in an amount at about 0.01% or more, about 0.03% or more, about 0.05% or more, about 0.07% or more, about 0.09% or more, about 0.1% or more, about 0.11% or more, about 0.12% or more, about 0.14% or more or about 0.15% or more. Alternatively, or in addition, the amount of first removal rate enhancer is about 0.25% or less, about 0.23% or less, about 0.21% or less, about 0.19% or less, about 0.18% or less, about 0.17% or less, or about 0.16% or less. In some embodiments, the first removal rate enhancer is present in an amount of about 0.13% or about 0.17%. In some embodiments, the amount of the first removal rate enhancer (i.e., alkanolamine) may be about 0.001% or more, or about 0.005% or more. In some embodiments, the amount of the first removal rate enhancer (i.e., alkanolamine) may be about 3% or less, about 2 wt. % or less, or about 1.5% or less. In some embodiments, the amount of the first removal rate enhancer (i.e., alkanolamine) may be more than 0.15%. The unit “%” referring to the amount of the first removal rate enhancer is all “wt. %” and is the ratio to the total weight of the polishing composition.

### 3. Second Removal Rate Enhancer

The polishing composition described herein contains a second removal rate enhancer. In some embodiments, the second removal rate enhancer is selected from a basic amino acid and a neutral amino acid. In some embodiments, the second removal rate enhancer is a basic amino acid. In some embodiments the second removal rate enhancer is a neutral amino acid.

In some embodiments, the basic amino acid is a natural amino acid, i.e., a L-amino acid. In some embodiments, the basic amino acid is selected from arginine, lysine and histidine. In some embodiments, the basic amino acid is arginine. In some embodiments, the basic amino acid is an un-natural amino acid, i.e., a D-amino acid. In some embodiments, the basic amino acid is a non-protein amino acid, i.e., ornithine. In a particular embodiment, the basic amino acid is L-arginine.

In some embodiments, the second removal rate enhancer further comprises a neutral amino acid selected from tryptophan and cysteine.

In some embodiments, the second removal rate enhancer is selected from L-arginine, L-lysine, L-histidine, L-ornithine, L-tryptophan and L-cysteine.

The amount the second removal rate enhancer present in the polishing composition can vary. In some embodiments, the amount of the second removal rate enhancer present in the polishing composition is in a range from about 0.1 wt. % to about 1.5 wt. %, about 0.1 wt. % to about 1.25 wt. %, from about 0.1 wt. % to about 1.0 wt. %, from 0.25 wt. % to about 0.75 wt. %, from about 0.30 wt. % to about 0.70 wt. %, from about 0.35 wt. % to about 0.65 wt. %, from about 0.40 wt. % to about 0.60 wt. %, or from about 0.45 wt. % to about 0.55 wt. %. In some embodiments, the amount of the second removal rate enhancer present in the polishing composition may be about 0.01 wt. % or more, or about 0.05 wt. % or more. In some embodiments, the amount of the second removal rate enhancer present in the polishing composition may be about 5 wt. % or less, about 4 wt. % or less, about 3 wt. % or less, or about 2 wt. % or less.

In some embodiments, the second removal rate enhancer is present in the polishing composition in an amount of about 0.1 wt. % or more, about 0.2 wt. % or more, about 0.3 wt. % or more, about 0.4 wt. % or more, or about 0.5 wt. % or more. Alternatively, or in addition, the amount of the second removal rate enhancer is present in the polishing composition can be about 1.0 wt. % or less, about 0.9 wt. % or less, about 0.8 wt. % or less, about 0.7 wt. % or less, about 0.6 wt. % or less, or about 0.5 wt. % or less. In some embodiments, the second removal rate enhancer is present in the polishing composition in an amount of about 0.50 wt. %.

4. pH-Adjusting Agent

The polishing compositions described herein may also contain a pH-adjusting agent. The pH-adjusting agent is not particularly limited. However, the pH of the polishing composition has a direct effect on the effectiveness of the polishing composition. In some embodiments, the alkanolamines and basic amino acid are not included in the scope of pH-adjusting agent.

In some embodiments, the pH-adjusting agent is an acidic compound. The choice of acid is not particularly limited provided that the strength of the acid is sufficient to lower the pH of the polishing composition of the present invention. The acidic pH adjuster may be an inorganic acid or an organic acid.

For example, and without limitation, such inorganic acids include hydrochloric acid, sulfuric acid, nitric acid, boric acid, carbonic acid, hypophosphorous acid, phosphorous acid, and phosphoric acid.

For example, and without limitation, such organic acids include formic acid, acetic acid, chloroacetic acid, propionic acid, butanoic acid, valeric acid, 2-methylbutyric acid, N-hexanoic acid, 3,3-dimethylbutanoic acid, 2-ethylbutanoic acid, 4-methylpentanoic acid, n-heptanoic acid, 2-methyl hexanoic acid, n-octanoic acid, 2-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, citrate, citric acid, lactic acid, diglycolic acid, 2-furancarboxylic acid, 3-furancarboxylic acid, 2-tetrahydrofurancarboxylic acid, methoxyacetic acid, methoxyphenylacetic acid, and phenoxyacetic acid. Such organic acids also include, without limitation, organic sulfonic acid, such as methanesulfonic acid, ethanesulfonic acid, and isethionic acid. In some embodiments, the pH adjusting agent is citric acid.

In an alternate embodiment, the pH-adjusting agent may be a mixture of an acidic agent and basic agent (such as a buffer). In such embodiments, the base is not particularly limited and may be appropriately selected from an inorganic basic compound such as an alkali metal hydroxide, an alkaline earth metal hydroxide, various carbonates, bicarbonates and the like may be used. Such basic compounds may be used singly or in combination of two or more types thereof.

Specific examples of the alkali metal hydroxide include potassium hydroxide, sodium hydroxide, ammonium hydroxide, and the like. Specific examples of the carbonate and bicarbonate include ammonium hydrogen carbonate, ammonium carbonate, potassium hydrogen carbonate, potassium carbonate, sodium hydrogen carbonate, sodium carbonate and the like.

In an alternate embodiment, the pH-adjusting agent may be a buffer containing phosphates, acetates, borates, sulfonates, carboxylates, nitrates and the like. For example, in some embodiments, ammonium salts can be used as a buffer. Such ammonium salts include, but are not limited to, ammonium sulfates, ammonium acetates, and/or ammonium nitrates.

In some embodiments, the pH of the polishing composition is in a basic region. Specifically, the pH may be more than 7.0, 8.0 or more, or 8.5 or more. In some embodiments, the pH of the polishing composition may be 14.0 or less, 13.0 or less, 12.0 or less, or 11.5 or less.

In some embodiments, the pH of the polishing composition is adjusted to a range from about 9.0 to about 11.0, from about 9.2 to about 11.0, from about 9.4 to about 11.0, from about 9.6 to about 11.0, from about 9.8 to about 11.0, from about 10.0 to about 11.0, from about 10.2 to about 11.0, from about 10.4 to about 11.0, from about 10.6 to about 11.0 or from about 10.8 to about 11.0. In some embodiments, the pH is less than about 11.0, less than about 10.8, less than about 10.6.0, less than about 10.4, less than about 10.2, less than about 10.0, less than about 9.8, or less than about 9.6. Alternatively, or in addition to, the pH is more than about 9.5, more than about 9.7, more than about 9.8, more than about 10.0, more than about 10.2, or more than about 10.4. In some embodiments, the pH is about from about 9.5 to about 10.5, or from about 9.8 to about 10.2. In some embodiments, the pH is about 10.0. The pH in the polishing composition herein can be measured using an any suitable apparatus known in the art (e.g., using ThermoFisher Scientific ORION (Trademark) VERSA STAR PRO (Trademark) pH/ISE/conductivity/dissolved oxygen multiparameter benchtop meter)

The pH-adjusting agent may be present at a specific concentration range, regardless of pH. For example, in some embodiments, the amount of pH-adjusting agent is in a range from about 0.0001 wt. % to about 0.1 wt. %, from about 0.003 wt. % to about 0.1%, from about 0.005 wt. % to about 0.1 wt. %, from about 0.007 wt. % to about 0.1 wt. %, or from about 0.01 wt. % to about 0.1 wt. %. In some embodiments, the amount of pH-adjusting agent is in the from about 0.01 wt. % to about 1.0 wt. %, from about 0.01 wt. % to about 0.7 wt. %, from about 0.01 wt. % to about 0.5 wt. %, from about 0.01 wt. % to about 0.1 wt. %. In some embodiments, the amount of pH-adjusting agent is present in an amount of at least about 0.0001 wt. %, at least about 0.001 wt. %, at least about 0.003 wt. %, at least about 0.005 wt. %, at least about 0.007 wt. %, or at least about 0.01 wt. %. In some embodiments, the pH-adjusting agent is present in an amount of less than about 1 wt. %, less than about 0.5 wt. %, less than about 0.1 wt. %, or less than about 0.05 wt. %. In some embodiments, the amount of pH-adjusting agent is in a range from about 0.01 wt. % to about 0.1 wt. %. In some embodiments, the amount of pH-adjusting agent contained in the polishing composition may be a suitable amount so that the pH of the polishing composition achieves a desirable numerical value.

### 5. Water

In an embodiment, the polishing compositions disclosed herein contain a carrier, medium, or vehicle. In an embodiment, the carrier, medium, or vehicle is water. Ion exchanged water (deionized water), pure water, ultrapure water, distilled water and the like may be used as the water. In order to reduce the number of unwanted components present in the water, the purity of water may be increased by operations such as removal of impurity ions with an ion exchange resin, removal of contaminants with a filter, and/or distillation. In an embodiment, the polishing compositions disclosed herein contain an aqueous carrier. The aqueous carrier has functions to dissolve or disperse components contained in the polishing compositions. In an embodiment, the aqueous carrier includes water. In an embodiment, 80 wt. % or more, 85 wt. % or more, 90 wt. % or more, 95 wt. % or more, or 99 wt. % or more, of the aqueous carrier consists of water.

In some embodiments, the water is relatively free of impurities. In some embodiments, the electric conductivity of the water is from about 0.05 mS/m to about 1 mS/m. In some embodiments, the total organic carbon (TOC) of the water is less than 50 ppb.

### 6. Additional Components

In an embodiment, the polishing compositions disclosed herein may contain additional components such as polymers, chelating agents, biocides, surfactants, or co-solvents. When a substrate, which is the object to be polished, is hydrophobic, the polishing composition contains a polymer whereby wetting properties of the substrate surface are expected to enhance by the effects of the polymer. Additionally, or alternatively, the compositions disclosed herein can include other additives as will be understood by those skilled in the art. In an embodiment the polymer is a water-soluble polymer. The “water-soluble” herein means that the solubility to water (25° C.) is 1 g/100 mL or more, and the “polymer” refers to a (co) polymer that has 200 or more in at least one of the weight average molecular weight (Mw) and number average molecular weight (Mn). In an embodiment, the number average molecular weight of the polymer is 10,000 to 2,000,000, 50,000 to 1,000,000, 100,000 to 500,000, or 300,000 to 400,000. For the number average molecular weight, values of the number average molecular weight or weight average molecular weight (in terms of polyethylene glycol) measured by gel permeation chromatography (GPC) can be used. The number average molecular weight can be measured by, for example, using a GPC apparatus made by SHIMADZU CORPORATION.

In an embodiment, the additional component may any material containing one or more α-glycosidic bonds. In some embodiments, such a material includes a polysaccharide. In some embodiments, the polysaccharide is water soluble. Exemplary water-soluble polysaccharides include, but are not limited to, pullulan, starch, amylose, amylopectin, gum Arabic (gum ghatti), locus bean gum (galactomannan). Konjac glucomannan, and cereal β-glucan. In some embodiments, the polysaccharide is pullulan. The amount of polysaccharide present in the polishing composition can vary. In some embodiments, the polysaccharide is present in the polishing composition in an amount 0.001 wt. % to about 0.015 wt. %, from about 0.001 wt. % to about 0.01 wt. %, from about 0.002 wt. % to about 0.008 wt. %, from about 0.004 wt. % to about 0.008 wt. %, from about 0.005 wt. % to about 0.007 wt. %. In some embodiments, the amount of polysaccharide present in the polishing composition is 0.006 wt. %.

In an embodiment, the additional component may include a chelating agent. The chelating agent chelates metal ions that may be generated during polishing, whereby it is expected that such ions do not remain after polishing on the surface of a substrate (e.g., bare silicon) to be polished. Incidentally, metal ions can be originated from a pad, a pad conditioner, or a polishing instrumentation. Non-limiting examples of the chelating agent include inorganic acids, organic acids, amines, and amino acids such as glycine, alanine, citric acid, acetic acid, maleic acid, oxalic acid, malonic acid, phthalic acid, succinic acid, nitrilotriacetic acid, iminodiacetic acid, ethylenediamine, DTPA (Diethylene triamine penta acetic acid), CDTA (Cyclohexane diamine tetra acetic acid), EDTA (Ethylene diamine tetra acetic acid), TTHA (Triethylene tetramine hexa acetic acid), HEDP (1-Hydroxy ethylidene-1,1-diphosphonic acid), NTMP (Nitrilo tri methyl phosphonic acid), PBTC (2-Phosphono butane-1,2,4-tricarboxylic acid), and EDTMP (Ethylene diamine tetramethylene phosphonic acid).

In an embodiment, examples of the usable chelating agent in the present invention include amino carboxylic acid chelating agents, phosphonate chelating agents, and the like. The chelating agents usable in the present invention are compounds represented by the formula below and salts thereof:

### [Formula 1]

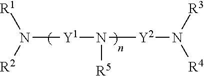

In the formula, Y¹ and Y² each independently represent a straight-chain or branched-chain alkylene group having 1 to 5 carbon atoms, n is an integer of 0 or more and 4 or less, R¹ to R⁵ are each independently a phosphonic acid group, a carboxyl group, a phosphonic acid group-substituted alkyl group, or a carboxyl group-substituted alkyl group. The salt is preferably acetates, phosphonates, and the like.

In an embodiment, the additional component may be a biocide. Non-limiting examples of biocides include hydrogen peroxide, quaternary ammonium compounds, and chlorine compounds. More specific examples of the quaternary ammonium compounds include, but are not limited to, methylisothiazolinone, tetramethylammonium chloride, tetraethylammonium chloride, tetrapropylammonium chloride, alkylbenzyldimethylammonium chloride, and alkylbenzyldimethylammonium hydroxide, wherein the alkyl chain ranges from 1 to about 20 carbon atoms. More specific examples of the chlorine compounds include, but are not limited to, sodium chlorite and sodium hypochlorite. Additional examples of biocides include biguanide, aldehydes, ethylene oxide, isothiazolinone, iodophor, Kordek™ MLX from DuPont (which is an aqueous composition of 2-methyl-4-isothiazolin-3-one). KATHON™ and NEOLENE™ product families that are commercially available from Dow chemicals, and the Preventol™ family from Lanxess. In an embodiment, the biocide is Kordek™ MLX. The amount of biocide used in the polishing composition may range from about 0.00005 wt. % to 0.01 wt. % or from about 0.0001 wt. % to 0.005 wt. %. In some embodiments, the biocide is present in an amount about 0.0005 wt. %, about 0.001 wt. %, or about 0.005 wt. %.

In another embodiment, the additional component may include a surfactant. The surfactants may be anionic, cationic, nonionic, or zwitterionic and may increase lubricity of the vehicle or compositions. Non-limiting examples of the surfactants are dodecyl sulfates, sodium salts or potassium salts, lauryl sulfates, secondary alkane sulfonates, alcohol ethoxylate, acetylenic diol surfactant, quaternary ammonium-based surfactants, amphoteric surfactants, such as betaines and amino acid derivatives-based surfactants, and any combination thereof. Examples of suitable commercially available surfactants include TRITON™. TERGITOL™, and the DOWFAX™ family of surfactants manufactured by Dow Chemicals. Suitable surfactants of surfactants may also include polymers comprising ethylene oxide (EO) and propylene oxide (PO) groups. An example of EO-PO polymer is TETRONIC™ 90R4 from BASF Chemicals. The amount of surfactant used in the polishing composition may range from about 0.0005 wt. % to 0.15 wt. %, preferably from 0.001 wt. % to 0.05 wt. %, and more preferably from 0.0025 wt. % to 0.025 wt. %.

In another embodiment, the additional component may include another solvent, termed a co-solvent. Non-limiting examples of co-solvents include, but are not limited to, alcohol (such as methanol or ethanol), ethyl acetate, tetrahydrofuran, alkanes, tetrahydrofuran, dimethylformamide, toluene, ketones (such as acetone), aldehydes, and esters. Other non-limiting examples of co-solvents include dimethyl formamide, dimethyl sulfoxide, pyridine, acetonitrile, glycols, and mixtures thereof. The co-solvent may be employed in various amounts, preferably from a lower limit of about 0.0001, 0.001, 0.01, 0.1, 0.5, 1, 5, or 10% (wt. %) to an upper limit of about 0.001, 0.01, 0.1, 1, 5, 10, 15, 20, 25, or 35% (wt. %).

As described herein, the polishing compositions have specific properties, which are greatly influenced by the components in the composition, both in type and amount. Thus, certain materials may need to be excluded from the composition in order to maintain the desired properties.

The polishing slurries of the invention can be prepared by any suitable technique, many of which are known to those skilled in the art. The polishing composition can be prepared in a batch or a continuous process. Generally, the polishing composition can be prepared by combining the components disclosed herein in any order. The term “component” as used herein includes individual ingredients (e.g., silica abrasive, first removal rate enhancer, second removal rate enhancer, and the like), as well as any combination of ingredients. For example, the abrasive can be dispersed in water, the first and second removal rate enhancers, and any other additive material can be added, and mixed by any method that is capable of incorporating the components into the polishing composition. The pH can be further adjusted, if desired, at any suitable time by addition of an acid, base or a buffer, as needed.

Accordingly, the polishing compositions described herein have specific properties exemplified by their performance in Si removal rate, low insoluble polish debris formation, and/or minimal observed changes in turbidity as the pH of the polishing composition decreases.

For the polishing compositions disclosed herein, the silica abrasive and first removal rate enhancer are present at a weight ratio of about 10:1 to about 1:10, from about 8:1 to about 1:8, from about 5:1 to about 1:5, from about 3:1 to about 1:3, from about 3:2 to about 2:3, from about 3:2 to about 1:1. In some embodiments, the amount of silica abrasive present in the disclosed polishing compositions is higher than the amount of the first removal rate enhancer. In such embodiments, the silica abrasive and the first removal rate enhancer are present at a weight ratio of about 5-2:1, about 4-2:1, about 3-2:1, about 2.5-2:1, or about 2.5-1.5:1. In some embodiments, the silica abrasive and the first removal rate enhancer are present at a weight ratio ranging from about 5:1 to about 1:1, from about 4:1 to about 1:1, from about 3:1 to about 1:1, from about 2.5:1 to about 1:1, or from about 2:1 to about 1:1. In some embodiments, the silica abrasive and the first removal rate enhancer are present in the disclosed polishing compositions at a weight ratio of about 2:1 to about 1:1. In one embodiment, the silica abrasive and the first removal rate enhancer are present in the polishing composition at a weight ratio of about 2:1.

For the polishing compositions disclosed herein, the silica abrasive and the second removal rate enhancer are present at a weight ratio of about 10:1 to about 1:10, from about 8:1 to about 1:8, from about 5:1 to about 1:5, from about 1:3 to about 3:1, from about 2.5:1 to about 1:2.5, or from about 1:1.5 to about 1.5:1. In some embodiments, the amount of silica abrasive present in the disclosed polishing compositions is lower than the amount of the second removal rate enhancer. In such embodiments, the silica abrasive and the second removal rate enhancer are present at a weight ratio of about 1:5-2, about 1:4-2, about 1:3-2, about 1:2.5-2, about 1:2.5-1.5, or from about 1:2.0-1.5. In some embodiments, the silica abrasive and the second removal rate enhancer are present in the disclosed polishing compositions at a weight ratio of about 1:1.5 to 1:2.5. In one embodiment, the silica abrasive and the second removal rate enhancer are present in the polishing composition at a weight ratio of about 1:1.67.

For the polishing compositions disclosed herein, the first removal rate enhancer and the second removal rate enhancer are present at a weight ratio of about 10:1 to about 1:10, from about 8:1 to about 1:8, from about 5:1 to about 1:5, from about 1:3.5 to about 3.5:1. In some embodiments, the amount of the first removal rate enhancer present in the disclosed polishing compositions is lower than the amount of the second removal rate enhancer. In such embodiments, the silica abrasive and the second removal rate enhancer are present at a weight ratio of about 1:5-2, about 1:4-2, about 1:3.5-2.5, or from about 1:3.5-3.0. In some embodiments, the first removal rate enhancer and the second removal rate enhancer are present in the disclosed polishing compositions at a weight ratio of about 1:2.5 to 1:3.5. In one embodiment, the silica abrasive and the second removal rate enhancer are present in the polishing composition at a weight ratio of about 1:3.33. In some embodiments, the first removal rate enhancer and the second removal rate enhancer are present in the disclosed polishing compositions at a weight ratio of about 1:3.5 to 1.2, about 1:3.0 to 1.3, or about 1:2.0 to 1.4.

For the polishing compositions disclosed herein, the polishing compositions have a silicon (Si) removal rate of at least about 0.5 μm/min; at least about 0.6 μm/min; at least about 0.7 μm/min; at least about 0.8 μm/min; at least about 0.9 μm/min; at least about 1.0 μm/min; or at least about 1.1 μm/min. In addition, or in the alternative, the polishing compositions have a Si removal rate of less than about 2.0 μm/min, less than about 1.8 μm/min, less than about 1.5 μm/min, less than about 1.25 μm/min, less than about 1.2 μm/min, less than about 1.1 μm/min, less than about 1.0 μm/min, less than about 0.95 μm/min, less than about 0.90 μm/min, less than about 0.85 μm/min, or less than about 0.80 μm/min. In some embodiments, the Si removal rate is in a range from about 0.5 μm/min to about 2.0 μm/min; from about 0.75 μm/min to about 2.0 μm/min, from about 0.7 μm/min to about 1.3 μm/min; from about 0.8 μm/min to about 1.2 μm/min; or from about 0.8 μm/min to about 1.1 μm/min.

For the polishing compositions disclosed herein, the polishing compositions have a Si: W, SiN, TEOS, TiN, Cu and/or Mo removal rate ratio greater than about 10, about 20, about 30, about 40, about 50, about 60, about 70, about 80, about 90, about 100, about 125, about 150, about 175, about 200, about 300, about 400, about 500. In some embodiments, the Si: W, SiN, TEOS, TIN, Cu and/or Mo removal rate ratio is in a range from about 100 to about 1000, from about 100 to about 1000, from about 200 to about 1000, from about 300 to about 1000, from about 40 to about 1000, or from about 5000 to 1000.

For the polishing compositions disclosed herein, the polishing compositions exhibit a turbidity of less than about 100 NTU, less than about 99 NTU, less than about 98 NTU, less than about 97 NTU, less than about 96 NTU, less than about 95 NTU, less than about 94 NTU, less than about 93 NTU, less than about 92 NTU, less than about 91 NTU, or less than about 90 NTU at a pH selected from about 10, about 6.5 and about 5.0 when measured according to the Fujimi Turbidity Protocol. In addition, or in the alternative, the disclosed polishing compositions exhibit a turbidity or at least about 85 NTU, at least about 86 NTU, at least about 87 NTU, at least about 88 NTU, at least about 89 NTU, at least about 90 NTU, at least about 91 NTU, at least about 92 NTU, at least about 93 NTU, at least about 94 NTU, at least about 95 NTU, at least about 96 NTU, at least about 97 NTU, or at least about 98 NTU at a pH selected from about 10, about 6.5 and about 5.0 when measured according to the Fujimi Turbidity Protocol.

For the polishing compositions disclosed herein, the disclosed polishing compositions exhibit a change in turbidity of no more than about 10%, about 9%, about 8%, about 7%, about 6%, about 5%, about 4%, about 3%, about 2%, or about 1% when decreasing the pH of the polishing composition from about 10.0 to about 6.5 according to the Fujimi Turbidity Protocol. In some embodiments, the disclosed polishing compositions exhibit no change in turbidity when decreasing the pH of the polishing composition from about 10.0 to about 6.5 according the Fujimi Turbidity Protocol. In some embodiments, the disclosed polishing compositions exhibit a change in turbidity ranging from about 0% to about 5%, from about 0% to about 4.5%, from about 0% to about 4%, from about 0% to about 3.5%, from about 0% to about 3%, from about 0% to about 2.5%, from about 0% to about 2%, from about 0% to about 1.5%, from about 0% to about 1%. In some embodiments, the disclosed polishing composition exhibits a minimal change in turbidity, i.e., a change of less than about 5%.

Accordingly, as described herein, in some embodiments are polishing compositions comprising a silica abrasive, a first removal rate enhancer and a second removal rate enhancer, wherein the first removal rate enhancer is an alkanolamine; and the second removal rate enhancer is a basic amino acid, and wherein the polishing composition has a pH ranging from about 9.0 to about 11.0.

As in any embodiment above, the polishing composition wherein the polishing composition exhibits a change in turbidity of no more than 10% when decreasing the pH of the polishing composition from a basic pH ranging from about 9.0 to 11.0 to an acidic pH ranging from about 6.5 to about 5 according to the Fujimi Turbidity Protocol. As in any embodiment above, the polishing composition wherein changes in turbidity are due to the formation of insoluble silica-containing polish byproducts.

As in any embodiment above, the polishing composition wherein the insoluble silica-containing polish byproducts are formed during polycondensation of silicon oxide species originating from the silica abrasive.

As in any embodiment above, the polishing composition wherein the turbidity is less than 100 NTU at a pH of 10 when measured according to the Fujimi Turbidity Protocol.

As in any embodiment above, the polishing composition wherein the turbidity changes by no more than 10% when decreasing the pH of the polishing composition from about 10.0 to about 6.5 according to the Fujimi Turbidity Protocol.

As in any embodiment above, the polishing composition wherein the first removal rate enhancer reduces polycondensation of silicon oxide species.

As in any embodiment above, the polishing composition wherein the first removal rate enhancer is an alkanolamine selected from the group consisting of monomethyl ethanolamine (MMEA), methyl diethanolamine (MDEA), dimethyl ethanolamine (DMEA) and a combination thereof.

As in any embodiment above, the polishing composition wherein the alkanolamine is acyclic containing no more than one nitrogen atom.

As in any embodiment above, the polishing composition wherein the first removal rate enhancer is MMEA or MDEA.

As in any embodiment above, a polishing composition wherein the first removal rate enhancer is present in an amount ranging from 0.10 wt. % to about 0.30 wt. %.

As in any embodiment above, a polishing composition wherein the second removal rate enhancer is a basic amino acid selected from the group consisting of L-arginine, L-histidine, L-lysine L-ornithine and the combination thereof.

As in any embodiment above, a polishing composition wherein the second removal rate enhancer is L-arginine.

As in any embodiment above, a polishing composition wherein the second removal rate enhancer is present at a concentration from about 0.1 wt. % to about 1.0 wt. %.

As in any embodiment above, a polishing composition wherein the first removal rate enhancer and the second removal rate enhancer are present in a weight ratio of about 1:2.0 to 1:4.0.

As in any embodiment above, a polishing composition wherein the silica abrasive has a mean particle size ranging from about 60 nm to about 80 nm.

As in any embodiment above, a polishing composition wherein the silica abrasive is present at a concentration of from about 0.1 wt. % to about 0.5 wt. %.

As in any embodiment above, a polishing composition wherein the silica abrasive and the first removal rate enhancer are present as a weight ratio of about 2:1 to 1:1.

As in any embodiment above, a polishing composition wherein the silica abrasive and second removal rate enhancer are present as a weight ratio of about 1:1.5 to 1:2.5.

As in any embodiment above, a polishing composition wherein the polishing composition has a pH ranging from about 9.5 to less than 10.5.

As in any embodiment above, a polishing composition further comprising a pH-adjusting agent.

As in any embodiment above, a polishing composition wherein the pH-adjusting agent is an acid present in a concentration from about 0.001 wt. % to about 0.01 wt. %.

As in any embodiment above, a polishing composition wherein the pH adjusting agent is citric acid.

As in any embodiment above, a polishing composition further comprising a polymer present in a concentration of from about 0.001 to about 0.1 wt. %.

As in any embodiment above, a polishing composition wherein the polymer is selected from pullulan, starch, amylose, amylopectin, gum Arabic (gum ghatti), locus bean gum (galactomannan). Konjac glucomannan cereal β-glucan the combination thereof.

As in any embodiment above, a polishing composition wherein the polishing composition is stable for a period of at least one week. In an embodiment, the pH of the composition remains unchanged after a period of at least one week. In another embodiment, the electrical conductivity (EC) of the composition remains unchanged after a period of at least one week. In some embodiments, the electrical conductivity is from greater than zero to about 10.0 mS/cm, from greater than zero to about 8.0 mS/cm, from greater than zero to about 7.5 mS/cm, from greater than zero to about 7.0 mS/cm, from greater than zero to about 6.5 mS/cm, from greater than zero to about 6.0 mS/cm, from greater than zero to about 5.5 mS/cm, from greater than zero to about 5.0 mS/cm, from greater than zero to about 4.5 mS/cm, or from greater than zero to about 4.0 mS/cm. In some embodiments, the electrical conductivity is from about 0.01 mS/cm to about 1.0 mS/cm, from about 0.02 mS/cm to about 0.50 mS/cm, or from about 0.03 mS/cm to about 0.1 mS/cm. In some embodiments, the electrical conductivity is about 0.02, 0.03, 0.04, 0.05, 0.06, 0.07, 0.08, 0.09, 0.10, 0.11, 0.12, 0.13, 0.14, or 0.15 mS/cm. In some embodiments, the upper limit of the electrical conductivity is about 0.25 mS/cm, about 0.20 mS/cm, about 0.18 mS/cm, about 0.16 mS/cm, about 0.14 mS/cm, about 0.12 mS/cm, about 0.10 mS/cm, about 0.08 mS/cm, about 0.07 mS/cm, about 0.06 mS/cm, about 0.05 mS/cm, about 0.04 mS/cm, or about 0.03 mS/cm. In a further embodiment, the electrical conductivity is in the range from about 0.2 mS/cm to about 1.0 mS/cm.

Further, in some embodiments, a polishing composition comprising a silica abrasive, a first removal rate enhancer and a second removal rate enhancer, the polishing composition has a mean particle size ranging from about 65 nm to about 75 nm and is present at a concentration of from about 0.25 wt. % to about 0.35 wt. %; the first removal rate enhancer is MMEA or MDEA and is present in an amount ranging from about 0.10 to about 0.15 wt. %; the second removal rate enhancer is L-arginine and present in an amount ranging from about 0.25 to about 0.75 wt. %., and wherein the polishing composition has a pH ranging from about 10.0 to about 10.5.

As in any embodiment above, a polishing composition further comprising citric acid as a pH adjusting agent.

As in any embodiment above, a polishing composition wherein the Si removal rate (RR) ranges from about 0.7 μm/min or more, or about 0.75 μm/min to about 2.0 μm/min.

As in any embodiment above, a polishing composition wherein the Si removal rate is higher than the removal rate of W, SiN, TIN, TEOS, Cu and/or Mo.

In an embodiment, the polishing compositions disclosed herein may be used for polishing a substrate. The substrate may comprise a Si layer. In an embodiment, the substrate comprises a layer of W, SiN, TIN, TEOS, Cu, Mo, or a combination thereof. In an embodiment, the polishing compositions disclosed herein are used for polishing a substrate having a bare silicon layer.

### C. Methods of Using the Polishing Compositions

The polishing compositions described herein are useful for polishing any suitable substrate. In an embodiment, the substrate to be polished can be any suitable substrate, which comprises at least one layer of silicon (Si). In another embodiment, the polishing composition can be used to polish a substrate comprising a silica layer. Suitable substrates include, but are not limited to, flat panel displays, integrated circuits, memory or rigid disks, metals, semiconductors, ILD devices, microelectromechanical systems (MEMS), ferroelectrics, and magnetic heads.

In some embodiments, the substrate may further comprise at least one other layer. In some embodiments, the other layer contains a metal such as tungsten (W), molybdenum (Mo), and/or copper (Co).

In some embodiments, the substrate can further comprise at least one other layer, e.g., an insulating layer. The insulating layer can be a metal oxide, porous metal oxide, glass, organic polymer, fluorinated organic polymer, or any other suitable high- or low-K insulating layer. The insulating layer can comprise, consist essentially of, or consist of silicon oxide, SiN, or combinations thereof. The silicon oxide layer can comprise, consist essentially of, or consist of any suitable silicon oxide, many of which are known in the art. For example, the silicon oxide layer can comprise tetraethoxysilane (TEOS), high density plasma (HDP) oxide, borophosphosilicate glass (BPSG), high aspect ratio process (HARP) oxide, spin-on dielectric (SOD) oxide, chemical vapor deposition (CVD) oxide, plasma-enhanced tetraethyl orthosilicate (PETEOS), thermal oxide, or undoped silicate glass.

In some embodiments, the at least one other layer can be titanium nitride film (TiN). TiN thin films have recently been shown to exhibit many properties that make them suitable for many applications in the microelectronics industry, e.g., as an ohmic contact and/or a diffusion barrier for metals in semiconductor devices. In addition, TiN exists in several sub-stoichiometric forms which makes it possible to manipulate properties by controlling the nitrogen stoichiometry. This leads to variations in conductivity, color, optical behavior and hardness that are dependent solely on nitrogen concentration.

The subject matter disclosed herein also comprises a method for polishing a substrate with the polishing compositions described herein. The method of polishing a substrate comprises: (a) providing a substrate, (b) providing a polishing composition described herein, (c) applying the polishing composition to at least a portion of the substrate, and (d) abrading at least a portion of the substrate with the polishing composition to polish the substrate.

In the method of polishing a substrate, the polishing compositions disclosed herein have a silicon (Si) removal rate of at least about 0.5 μm/min; at least about 0.6 μm/min; at least about 0.7 μm/min; at least about 0.8 μm/min; at least about 0.9 μm/min; at least about 1.0 μm/min; or at least about 1.1 μm/min. In addition, or in the alternative, the polishing compositions have a Si removal rate of less than about 2.0 μm/min, less than about 1.8 μm/min, less than about 1.5 μm/min, less than about 1.25 μm/min, less than about 1.2 μm/min, less than about 1.1 μm/min, less than about 1.0 μm/min, less than about 0.95 μm/min, less than about 0.90 μm/min, less than about 0.85 μm/min, or less than about 0.80 μm/min. In some embodiments, the Si removal rate is in a range from about 0.5 μm/min to about 2.0 μm/min; from about 0.75 μm/min to about 2.0 μm/min, from about 0.7 μm/min to about 1.3 μm/min; from about 0.8 μm/min to about 1.2 μm/min; or from about 0.8 μm/min to about 1.1 μm/min.

In the method of polishing a substrate, the polishing compositions disclosed herein have a silicon removal rate that is higher than the removal rate of at least one or more of W, SiN, TEOS, TIN, Cu and/or Mo. In some embodiments, the silicon removal rate is higher by at least about 1%, about 5%, about 10%, about 15%, about 20%, about 25%, about 30%, about 35%, about 40%, about 45%, about 50%, about 55%, about 60%, about 65%, about 70%, about 75%, about 80%, about 85%, about 90%, or by at least 95% compared to the removal rate of at least one or more of W, SiN, TEOS, TiN, Cu and/or Mo.

In the method of polishing a substrate, the polishing compositions disclosed herein have a Si: W, SiN, TEOS, TiN, Cu and/or Mo removal rate ratio greater than about 10, about 20, about 30, about 40, about 50, about 60, about 70, about 80, about 90, about 100, about 125, about 150, about 175, or greater than about 200. In some embodiments, the Si: W, SiN, TEOS, TIN, Cu and/or Mo removal rate ratio is in a range from about 2 to about 200, from about 5 to about 175, from about 10 to about 150, from about 25 to about 125, from about 50 to about 100, or from about 60 to 80.

In the method of polishing a substrate, the polishing compositions disclosed herein exhibit a turbidity of less than about 100 NTU, less than about 99 NTU, less than about 98 NTU, less than about 97 NTU, less than about 96 NTU, less than about 95 NTU, less than about 94 NTU, less than about 93 NTU, less than about 92 NTU, less than about 91 NTU, or less than about 90 NTU at a pH selected from about 10, about 6.5 and about 5.0 when measured according to the Fujimi Turbidity Protocol. In addition, or in the alternative, the disclosed polishing compositions exhibit a turbidity or at least about 85 NTU, at least about 86 NTU, at least about 87 NTU, at least about 88 NTU, at least about 89 NTU, at least about 90 NTU, at least about 91 NTU, at least about 92 NTU, at least about 93 NTU, at least about 94 NTU, at least about 95 NTU, at least about 96 NTU, at least about 97 NTU, or at least about 98 NTU at a pH selected from about 10, about 6.5 and about 5.0 when measured according to the Fujimi Turbidity Protocol.

In the method of polishing a substrate, the polishing compositions disclosed herein exhibit a change in turbidity of no more than about 10%, about 9%, about 8%, about 7%, about 6%, about 5%, about 4%, about 3%, about 2, or about 1 when decreasing the pH of the polishing composition from about 10.0 to about 6.5 according to the Fujimi Turbidity Protocol. In some embodiments, the disclosed polishing compositions exhibit no change in turbidity when decreasing the pH of the polishing composition from about 10.0 to about 6.5 according the Fujimi Turbidity Protocol. In some embodiments, the disclosed polishing compositions exhibit a change in turbidity ranging from about 0% to about 5%, from about 0.5% to about 4.5%, from about 1% to about 4.5%, from about 1.5% to about 4.0%, or from about 2% to about 3%.

Thus, as described herein, in some embodiments are methods of using the polishing compositions, where the methods comprise the steps of a) providing the polishing composition disclosed herein; b) providing a substrate, wherein the substrate comprises a silicon-containing layer (Si as an object to be polished); and c) polishing the substrate with the polishing composition to provide a polished substrate.

As in any embodiment above, a method wherein the substrate is a semiconductor.

As in any embodiment above, a method wherein the Si removal rate (RR) ranges from about 0.7 μm/min or more, or about 0.75 μm/min to about 2.0 μm/min.

As in any embodiment above, a method further comprising a step of diluting the polishing composition of step (a) at least from about 1-fold to about 5-fold with a diluent.

As in any embodiment above, a method wherein the diluent is water.

As in any embodiment above, a method wherein the substrate further comprises a layer of W, SiN, TiN, TEOS, Cu, Mo, or a combination thereof.

As in any embodiment above, a method wherein during polishing step (c) the first RR enhancer reduces the formation of silicon oxide species which can form insoluble silica-containing polish byproducts.

### D. Examples

The following preparations and examples are given to enable those skilled in the art to more clearly understand and to practice the present invention. They should not be considered as limiting the scope of the invention, but merely as being illustrative and representative.

In one aspect, disclosed are methods of making the polishing compositions. In another aspect are disclosed methods of using the polishing compositions to polish materials.

The present invention includes the following aspects and forms.
1. A polishing composition comprising a silica-containing abrasive, a first removal rate enhancer and a second removal rate enhancer, wherein the first removal rate enhancer is an alkanolamine without primary amine group; the second removal rate enhancer is a basic amino acid, and having a pH in a basic region.
2. The polishing composition of 1., wherein the alkanolamine is represented by N (R¹) (R²) (R³), R¹ to R³ are each independently selected from a hydrogen atom, an alkyl group having 1 to 4 carbon atoms, and a hydroxy group-substituted alkyl group having 1 to 4 carbon atoms, provided that at least one of R¹ to R³ is a hydroxy group-substituted alkyl group having 1 to 4 carbon atoms.
3. The polishing composition of 1, or 2., wherein the alkanolamine is acyclic containing one nitrogen atom.
4. The polishing composition of any one of 1. to 3., wherein the first removal rate enhancer is an alkanolamine selected from the group consisting of monomethyl ethanolamine (MMEA), methyl diethanolamine (MDEA), dimethyl ethanolamine (DMEA) and a combination thereof.
5. The polishing composition of any one of 1. to 4., wherein the first removal rate enhancer is present in an amount ranging from about 0.05 to 0.5 wt. %.
6. The polishing composition of any one of 1. to 5., wherein the second removal rate enhancer is L-arginine.
7. The polishing composition of any one of 1. to 6., wherein the first removal rate enhancer and the second removal rate enhancer are present in a weight ratio of about 1:1.5 to 1:3.5.
8. The polishing composition of any one of 1. to 7., wherein the abrasive and the first removal rate enhancer are present in a weight ratio of about 2:1 to 1:1.
9. The polishing composition of any one of 1. to 8., wherein the abrasive and the second removal rate enhancer are present in a weight ratio of about 1:1.5 to 1:2.5.
10. The polishing composition of any one of 1. to 0.9., comprising a polymer and/or a chelating agent.
11. The polishing composition of 10, wherein the polymer is selected from pullulan, starch, amylose, amylopectin, gum Arabic (gum ghatti), locus bean gum (galactomannan), Konjac glucomannan, and cereal β-glucan.
12. A polishing composition comprising a silica-containing abrasive, a first removal rate enhancer and a second removal rate enhancer, wherein the first removal rate enhancer is an alkanolamine selected from the group consisting of monomethyl ethanolamine (MMEA), methyl diethanolamine (MDEA), dimethyl ethanolamine (DMEA) and a combination thereof and present in an amount ranging from about 0.05 to 0.5 wt. %, the second removal rate enhancer is L-arginine and present in an amount ranging from about 0.1 to 1 wt. %, and having a pH in a range from about 9 to about 11.
13. A method for producing a substrate, the method comprising the steps of (a) providing the polishing composition of any of 1. to 12.; (b) providing a substrate, wherein the substrate comprises Si as an object to be polished; and (c) polishing the substrate with the polishing composition to provide a polished substrate.

### Example 1: Fujimi Turbidity Protocol

The following protocol was used to measure the turbidity and changes in turbidity as a function of pH for the disclosed polishing slurries. The protocol comprises the following steps:
Step 1: Measure the initial turbidity of the slurry by placing a 15 mL aliquot of the slurry into a cuvette. The slurry has a pH of 10.
Step 2: Place the cuvette from step 1 containing the slurry aliquot into a turbidity reader (Micro TPI, Scientific, Inc). This instrument operates as specified in ISO 7027 and DIN 27027 when measuring the turbidity of a sample. Read the turbidity of the sample at room temperature.
Step 3: Once the reading is complete, remove the cuvette from the reader and discard the slurry aliquot that was inside the cuvette. Clean the cuvette by rinsing the inside of the cuvette 3× with 15 mL deionized water (DIW).
Step 4: Take a 50 mL sample of the slurry in Step 1 and place the slurry sample into a 100 mL beaker. Lower the pH of the slurry by adding dropwise to the slurry an aqueous solution of 5% HNO3 while stirring. Continuously measure the pH of the slurry while adding aqueous solution of 5% HNO3 until the pH meter consistently reads a pH of 6.5. At that point, the pH has successfully been lowered from 10 to 6.5.
Step 5: Measure the turbidity of the acidified slurry sample from step 4 by placing a 15 mL aliquot of this slurry into the cleaned cuvette of step 3. The slurry has a pH of 6.5.
Step 6: Place the cuvette from step 5 containing the acidified slurry aliquot into the turbidity reader (Micro TPI, Scientific, Inc). Read the turbidity of the sample at room temperature.
Step 7: Once the reading is complete, remove the cuvette from the reader and discard the acidified slurry aliquot that was inside the cuvette. Clean the cuvette by rinsing the inside of the cuvette 3× with 15 mL deionized water (DIW).
Step 8: Take the acidified slurry from step 4, which has a pH of 6.5 and continue to lower the pH of the slurry by adding dropwise to this slurry an aqueous solution of 5% HNO3 while stirring. Continuously measure the pH of the slurry while adding aqueous solution of 5% HNO3 until the pH meter consistently reads a pH of 5.0. At that point, the pH has successfully been lowered from 6.5 to 5.0.
Step 9: Measure the turbidity of the acidified slurry sample from step 8 by placing a 15 mL aliquot of this slurry into the cleaned cuvette of step 7. The slurry has a pH of 5.0.
Step 10: Place the cuvette from step 9 containing the acidified slurry aliquot into the turbidity reader (Micro TPI, Scientific, Inc). Read the turbidity of the sample at room temperature.

Record all three readings form slurry aliquots at pH 10, 6.5 and 5.0, which are measured in NTU (Nephelometric turbidity unit)

### Example 2: Polishing Conditions

Materials and tools used:
Polishing conditions
200 mm Polisher Westech
Platen rotation speed: 112 rpm.
Head rotation speed: 93 rpm
Flow rate: 100 mL/min
Down force: 4 psi
Polishing time: 60 sec
Pad: Vision pad (Trademark) VP6000; Dupont.
Dilution factor: 1×

Instrumentation: Westech (200 mm polisher),

Polishing pad: VP6000,

Pad conditioner: 3M A165

Polishing recipe:
Down force: 4.0 psi,
rotation: 112/93 rpm,
slurry flow rate: 100 mL/min,
Polishing time: 60 sec

### Example 3: Evaluation of Various Polishing Compositions

For this study, Slurries A-H were prepared, differing in the type of first removal rate enhancer, which are shown below in Table 1. PL-3 uses ultra high purity colloidal silica made by Fuso Chemical Co., Ltd. Incidentally, the slurries use water as the aqueous carrier, and some slurries have citric acid added in a very small amount that does not significantly influence the pH change.

TABLE 1
Compositions of Slurries A-H

| | Abrasive | | | | | | | | |
|---|---|---|---|---|---|---|---|---|---|
| | | Average | | | | | | | |
| | | secondary | | RR Enhancer 1 | | RR Enhancer 2 | | | |
| | | particle | Conc. | | Conc. | | Conc. | pH | |
| Slurry | Type | size [nm] | [wt. %] | Type | [wt. %] | Type | [wt. %] | adjuster | pH |
| A | PL-3 | 70 | 0.3 | — | — | Arginine | 0.5 | — | 10 |
| B | PL-3 | 70 | 0.3 | AEEA | 0.15 | Arginine | 0.5 | — | 10 |
| C | PL-3 | 70 | 0.3 | MMEA | 0.15 | Arginine | 0.5 | Citric acid | 10 |
| | | | | | | | | (anhydrous) | |
| D | PL-3 | 70 | 0.3 | MDEA | 0.15 | Arginine | 0.5 | Citric acid | 10 |
| | | | | | | | | (anhydrous) | |
| E | PL-3 | 70 | 0.3 | AEEA | 0.15 | Arginine | 0.5 | Citric acid | 10 |
| | | | | | | | | (anhydrous) | |
| F | PL-3 | 70 | 0.3 | APM | 0.15 | Arginine | 0.5 | Citric acid | 10 |
| | | | | | | | | (anhydrous) | |
| G | PL-3 | 70 | 0.3 | AEP | 0.15 | Arginine | 0.5 | Citric acid | 10 |
| | | | | | | | | (anhydrous) | |
| H | PL-3 | 70 | 0.3 | DMEA | 0.15 | Arginine | 0.5 | Citric acid | 10 |
| | | | | | | | | (anhydrous) | |

* The value pH 10 in the above table is the value that is rounded off to one decimal place.

Table 2 summaries the chemical names for each first removal rate enhancer used in slurries A-H.

TABLE 2
List of First Removal Rate Enhancers

| Acronym | Chemical name | |
|---|---|---|
| AEP | Aminoethyl- piparazine | 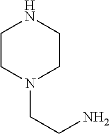 |
| AEEA | Aminoethyl- ethanolamine | 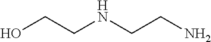 |
| APM | Aminopropyl- morpholine | 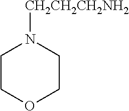 |
| MMEA | Monomethyl ethanolamine | 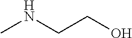 |
| MDEA | Methyldiethanol- amine | 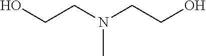 |
| DMEA | Dimethylethanol- amine | 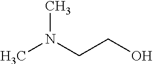 |

The silicon removal rates of Slurries A-H were determined as well as their turbidity and changes in turbidity when screened with the Fujimi Turbidity Protocol. The results are shown in Table 3 below:

TABLE 3
Silicon Removal Rates of Slurries A-H and Screening Results
of Slurries A-H in the Fujimi Turbidity Protocol

| | | Bare-Si | Turbidity (NTU) | | | | |
|---|---|---|---|---|---|---|---|
| | RR | RR | | | | NTU(pH 6.5) − | NTU(pH 5.0) − |
| Slurry | Enhancer 1 | [μm/min] | pH = 10 | pH = 6.5 | pH = 5.0 | NTU(pH 10) | NTU(pH 10) |
| A | | 0.60 | 93 | 130 | x | 37 | not calc. |
| B | AEEA | 1.05 | 91 | 145 | x | 54 | not calc. |
| C | MMEA | 0.82 | 92 | 88 | 87 | −4 | −5 |
| D | MDEA | 1.10 | 91 | 92 | 93 | 1 | 2 |
| E | AEEA | 1.08 | 95 | 145 | x | 50 | not calc. |
| F | APM | 0.75 | 97 | 120 | 145 | 23 | 48 |
| G | AEP | 1.50 | 88 | 270 | x | 182 | not calc. |
| H | DMEA | 0.72 | 94 | 95 | 96 | 1 | 2 |

* The value pH 10 in the above table is the value that is rounded off to one decimal place. The values pH 6.5, pH 5.0 are the values that are rounded off to two decimal places.

These results show that slurries C, D and H exhibit the least amount of turbidity changes upon lowering the pH of the polishing composition from 10 to 6.5 when tested in the Fujimi Turbidity Protocol. Slurries A and F exhibit moderate changes in turbidity upon lowering the pH of the polishing composition from 10 to 6.5 when tested in the Fujimi Turbidity Protocol, whereas slurries B and G notably exhibited the bigger changes in turbidity. Additionally, the comparison between the removal rate of slurry A and, for example, the removal rates of slurries C, D and H reveals that MMEA, MDEA and DMEA function as the removal rate enhancers.

The next study investigated slurries I-K, which differed in the amounts of first removal rate enhancer present in the polishing compositions and the effects of having a polymer and/or Chelator present in these polishing compositions (which were not present in slurries A-H above). The composition of slurries I-K is shown in Table 4 below. Incidentally, the slurries use water as the aqueous carrier, and these slurries have citric acid added in a very small amount that does not significantly influence the pH change.

TABLE 4
Compositions of Slurries I-K

| | Abrasive | | | | | | | | | | | | |
|---|---|---|---|---|---|---|---|---|---|---|---|---|---|
| | | Average | | | | | | | | | | | |
| | | secondary | | RR Enhancer 1 | | RR Enhancer 2 | | Chelator | | Polymer | | | |
| | | particle | Conc. | | Conc. | | Conc. | | Conc. | | Conc. | pH | |
| Slurry | Type | size [nm] | [wt. %] | Type | [wt. %] | Type | [wt. %] | Type | [wt. %] | Type | [wt. %] | adjuster | pH |
| I | PL-3 | 70 | 0.2 | MMEA | 0.15 | Arginine | 0.5 | DTPA | 0.01 | — | — | Citric acid | 10 |
| | | | | | | | | | | | | (anhydrous) | |
| J | PL-3 | 70 | 0.2 | MMEA | 0.15 | Arginine | 0.5 | DTPA | 0.01 | Pullulan | 0.006 | Citric acid | 10 |
| | | | | | | | | | | | | (anhydrous) | |
| K | PL-3 | 70 | 0.2 | MMEA | 0.29 | Arginine | 0.5 | DTPA | 0.01 | — | — | Citric acid | 10 |
| | | | | | | | | | | | | (anhydrous) | |

* The value pH 10 in the above table is the value that is rounded off to one decimal place.

The silicon removal rates and turbidity properties (when tested in the Fujimi Turbidity Protocol) were determined for slurries I-K. The Results of these studies are shown in Table 5.

TABLE 5
Silicon Removal Rates of Slurries I-K and Screening Results
of Turbidity Properties in the Fujimi Turbidity Protocol

| | | Bare-Si | Turbidity (NTU) | | | | |
|---|---|---|---|---|---|---|---|
| | | RR | | | | NTU(pH 6.5) − | NTU(pH 5.0) − |
| Slurry | pH | [μm/min] | pH = 10 | pH = 6.5 | pH = 5.0 | NTU(pH 10) | NTU(pH 10) |
| I | 10 | 0.79 | 92 | 88 | 89 | −4 | −3 |
| J | 10 | 0.82 | 92 | 89 | 88 | −3 | −4 |
| K | 10 | 0.83 | 92 | 88 | 89 | −4 | −3 |

* The value pH 10 in the above table is the value that is rounded off to one decimal place. The values pH 6.5, pH 5.0 are the values that are rounded off to two decimal places.

These results demonstrate that increasing the amount of the first removal rate enhancer in the polishing composition provides an increase in the silicon removal rate as is seen when comparing the silicon removal rates of slurries I and K. In addition, an increase was also observed when a polymer such a pullulan was added to the polishing composition as can be seen when comparing the silicon removal rates of slurries I and J. However, essentially no changes were observed with respect to turbidity properties of slurries I-K.

Lastly, slurries L-N in Table 6 were investigated, which did not include a second removal rate enhancer and differed in the type and amount of first removal rate enhancer. The compositions are shown below. Incidentally, the slurries use water as the aqueous carrier.

TABLE 6
Compositions of Slurries L-N

| | Abrasive | | | | | | | | | | |
|---|---|---|---|---|---|---|---|---|---|---|---|
| | | Average | | | | | | | | | |
| | | secondary | RR Enhancer 1 | | RR Enhancer 2 | | | Polymer | | | |
| | | particle | | Conc. | | Conc. | Chelator | | Conc. | pH | |
| Slurry | Type | size [nm] | Type | [wt. %] | Type | [wt. %] | Type | Type | [wt. %] | adjuster | pH |
| L | PL-3 | 70 | AEP | 0.79 | — | — | DTPA | — | — | — | 11 |
| M | PL-3 | 70 | APM | 0.4 | — | — | DTPA | — | — | — | 10.5 |
| N | PL-3 | 70 | — | — | — | — | DTPA | — | — | — | — |

* The value pH 11 in the above table is the value that is rounded off to one decimal place. The value pH 10.5 is the value that is rounded off to two decimal places.

Silicon removal rates of these slurries and their results when screened in the Fujimi Turbidity Protocol are shown in the table below.

TABLE 7
Silicon Removal Rates of Slurries L-N and Screening Results
of Turbidity Properties in the Fujimi Turbidity Protocol

| | Bare-Si | Turbidity (NTU) | | | | |
|---|---|---|---|---|---|---|
| | RR | | | | NTU(pH 6.5) − | NTU(pH 5.0) − |
| Slurry | [μm/min] | pH = 11 | pH = 9.4 | pH = 8.4 | NTU(pH 10) | NTU(pH 10) |
| L | 2.00 | 211 | x | x | — | — |
| M | 1.26 | 186 | 194 | 495 | 8 | 309 |
| N | 0.58 | — | — | — | — | — |

* The value pH 11 in the above table is the value that is rounded off to one decimal place. The values pH 9.4, pH 8.4 are the values that are rounded off to two decimal places.

The results in Table 7 essentially show that at least the first removal rate enhancer is required to obtain a high silicon removal rate as can be seen when comparing slurries L and M with N, which does not contain any removal rate enhancers. Furthermore, Table 7 suggests that while high silicon removal rates can be achieved in the absence of the second removal rate enhancer (see slurries L and M), beneficial turbidity properties were not observed. The comparison between the removal rate of slurry A (containing arginine) and the removal rate of slurry N (containing no arginine) reveals that arginine functions as the removal rate enhancer.

It will be apparent to those skilled in the art that various modifications and variations can be made in the present invention without departing from the scope or spirit of the invention. Other aspects of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A polishing composition comprising a silica-containing abrasive, a first removal rate enhancer and a second removal rate enhancer, wherein
the first removal rate enhancer is an alkanolamine without primary amine group; and
the second removal rate enhancer is a basic amino acid, and
having a pH in a basic region.

2. The polishing composition of claim 1, wherein the alkanolamine is represented by N (R¹) (R²) (R³), R¹ to R³ are each independently selected from a hydrogen atom, an alkyl group having 1 to 4 carbon atoms, and a hydroxy group-substituted alkyl group having 1 to 4 carbon atoms, provided that at least one of R¹ to R³ is a hydroxy group-substituted alkyl group having 1 to 4 carbon atoms.

3. The polishing composition of claim 1, wherein the alkanolamine is acyclic containing one nitrogen atom.

4. The polishing composition of claim 1, wherein the first removal rate enhancer is an alkanolamine selected from the group consisting of monomethyl ethanolamine (MMEA), methyl diethanolamine (MDEA), dimethyl ethanolamine (DMEA) and a combination thereof.

5. The polishing composition of claim 1, wherein the first removal rate enhancer is present in an amount ranging from about 0.05 to 0.5 wt. %.

6. The polishing composition of claim 1, wherein the second removal rate enhancer is L-arginine.

7. The polishing composition of claim 1, wherein the first removal rate enhancer and the second removal rate enhancer are present in a weight ratio of about 1:1.5 to 1:3.5.

8. The polishing composition of claim 1, wherein the abrasive and the first removal rate enhancer are present in a weight ratio of about 2:1 to 1:1.

9. The polishing composition of claim 1, wherein the abrasive and the second removal rate enhancer are present in a weight ratio of about 1:1.5 to 1:2.5.

10. The polishing composition of claim 1, comprising a polymer and/or a chelating agent.

11. The polishing composition of claim 10, wherein the polymer is selected from pullulan, starch, amylose, amylopectin, gum Arabic (gum ghatti), locus bean gum (galactomannan), Konjac glucomannan, cereal β-glucan and the combination thereof.

12. A polishing composition comprising a silica-containing abrasive, a first removal rate enhancer and a second removal rate enhancer, wherein
the first removal rate enhancer is an alkanolamine selected from the group consisting of monomethyl ethanolamine (MMEA), methyl diethanolamine (MDEA), dimethyl ethanolamine (DMEA) and a combination thereof and present in an amount ranging from about 0.05 to 0.5 wt. %,
the second removal rate enhancer is L-arginine and present in an amount ranging from about 0.1 to 1 wt. %, and
having a pH in a range from about 9 to about 11.

13. A method for producing a substrate, the method comprising the steps of
(a) providing the polishing composition of claim 1;
(b) providing a substrate, wherein the substrate comprises Si as an object to be polished; and
(c) polishing the substrate with the polishing composition to provide a polished substrate.
